(19) United States
(12) Patent Application Publication
(10) Pub. No.: US 2025/0379194 A1
(43) Pub. Date: Dec. 11, 2025

(54) SEMICONDUCTOR DEVICE INCLUDING EMBEDDED SEMICONDUCTOR DIES

(71) Applicant: Sandisk Technologies, Inc., Milpitas, CA (US)

(72) Inventors: Muhammad Faizul Bin Mohd Yunus, Penang (MY); Muhamad Ridhwan Hafiz bin Rosdi, Penang (MY); Cindirella Quinit Noromor, La Union (PH); Hubert Tolentino Helera, Laguna (PH)

(73) Assignee: Sandisk Technologies, Inc, Milpitas, CA (US)

(21) Appl. No.: 18/738,634

(22) Filed: Jun. 10, 2024

(51) Int. Cl. H01L 25/16; H01L 23/00; H01L 23/29; H01L 23/31; H01L 25/065; H10B 80/00

(52) U.S. Cl. CPC H01L 25/16; H01L 23/293; H01L 23/3121; H01L 23/3135; H01L 24/32; H01L 25/0657; H10B 80/00; H01L 24/48; H01L 24/73; H01L 2224/32225; H01L 2224/48145; H01L 2224/48227; H01L 2224/73265; H01L 2225/06506; H01L 2225/0651; H01L 2225/06562

(57) ABSTRACT

A semiconductor device includes one or more semiconductor dies mounted on a substrate and electrically coupled to the substrate for example using bond wires. In accordance with aspects of the present technology, a film layer may thereafter be applied over the one or more semiconductor dies and bond wires. In one example, the one or more semiconductor dies may include a stack of memory dies. In this example, a controller die or other component may be mounted on top of the film layer. In another example, the one or more semiconductor dies may include a controller die mounted directly to the substrate. In this example, a stack of one or more memory dies may be mounted on top of the film layer.

### BACKGROUND

The strong growth in demand for portable consumer electronics is driving the need for high-capacity storage devices. Non-volatile semiconductor memory devices, such as flash memory storage cards, are widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, cellular telephones and solid-state drives.

While many varied packaging configurations are known, flash memory storage packages may in general be fabricated as system-in-a-package (SiP) or multichip modules (MCM), where a plurality of memory dies are mounted and interconnected on a substrate. The dies may be electrically connected to each other and the substrate for example using bond wires. A controller die, such as an ASIC, is often mounted on the substrate next to the memory die stack. Once electrical connections between the controller/memory dies and the substrate are made, the assembly is then typically encased in a molding compound which provides a protective enclosure.

Innovations in flash memory die fabrication are enabling memory dies to be made smaller and thinner without sacrificing storage capacities. While advantageous from a storage capacity standpoint, working with smaller memory dies is more difficult as they are more prone to chip or crack during the package assembly process than thicker, larger dies. Moreover, there is a need to minimize the footprint of the substrate and overall package. This makes positioning of the memory dies and controller die side-by-side less practical.

### DESCRIPTION OF THE DRAWINGS

FIG. 1 is a flowchart of the overall assembly process of semiconductor device according to embodiments of the present invention.

FIG. 2 is an edge view of a substrate for use in forming the semiconductor device according to an embodiment of the present technology.

FIG. 3 is a top view of the semiconductor device shown in FIG. 4.

FIG. 4 is an edge view of a substrate and a stack of memory dies for forming the semiconductor device according to an embodiment of the present technology.

FIG. 5 is a top view of the semiconductor device shown in FIG. 6.

FIG. 6 is an edge view of a substrate and a stack of memory dies encased in a film layer for forming the semiconductor device according to an embodiment of the present technology.

FIG. 7 is a top view of the semiconductor device shown in FIG. 6.

FIG. 8 is a perspective view of the semiconductor device shown in FIG. 6.

FIG. 9 is an edge view of a substrate and a stack of memory dies encased in a film layer with a component mounted on the film layer according to an embodiment of the present technology.

FIG. 10 is a top view of the semiconductor device shown in FIG. 9.

FIG. 11 is a perspective view of the semiconductor device shown in FIG. 9.

FIG. 12 is an edge view of a completed semiconductor device encapsulated in mold compound according to embodiments of the present technology.

FIG. 13 is an edge view of a substrate and a controller die wire bonded to the substrate in the formation of a semiconductor device according to an alternative embodiment of the present technology.

FIG. 14 is a top view of the semiconductor device shown in FIG. 13.

FIG. 15 is an edge view of a substrate and a controller die flip-chip mounted to the substrate in the formation of a semiconductor device according to an alternative embodiment of the present technology.

FIG. 16 is an edge view of a substrate and controller die encased in a film layer for forming a semiconductor device according to an alternative embodiment of the present technology.

FIG. 17 is a top view of the semiconductor device shown in FIG. 16.

FIG. 18 is an edge view of a substrate and controller die encased in a film layer with a memory die stack mounted on a film layer according to an alternative embodiment of the present technology.

FIG. 19 is a top view of the semiconductor device shown in FIG. 18.

FIG. 20 is an edge view of a completed semiconductor device encapsulated in mold compound according to an alternative embodiment of the present technology.

### DETAILED DESCRIPTION

The present technology will now be described with reference to the figures, which in embodiments, relate to a semiconductor device including one or more semiconductor dies mounted on a substrate and electrically coupled to the substrate for example using bond wires. In accordance with aspects of the present technology, a film layer may thereafter be applied over the one or more semiconductor dies and bond wires. In one example, the one or more semiconductor dies may be a stack of memory dies. In this example, a controller die or other component may be mounted on top of the film layer. In another example, the one or more semiconductor dies may be a controller die mounted directly to the substrate. In this example, a stack of one or more memory dies may be mounted on top of the film layer. The film layer provides a number of advantages, including protecting the memory stack or controller die, and bond wires, during the semiconductor device assembly.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.15 mm, or alternatively, ±2.5% of a given dimension.

For purposes of this disclosure, a connection may be a direct connection or an indirect connection (e.g., via one or more other parts). In some cases, when a first element is referred to as being connected, affixed, mounted or coupled to a second element, the first and second elements may be directly connected, affixed, mounted or coupled to each other or indirectly connected, affixed, mounted or coupled to each other. When a first element is referred to as being directly connected, affixed, mounted or coupled to a second element, then there are no intervening elements between the first and second elements (other than possibly an adhesive or melted metal used to connect, affix, mount or couple the first and second elements).

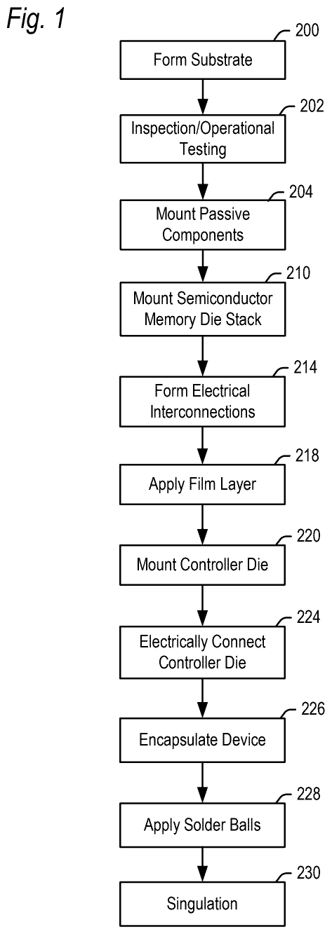

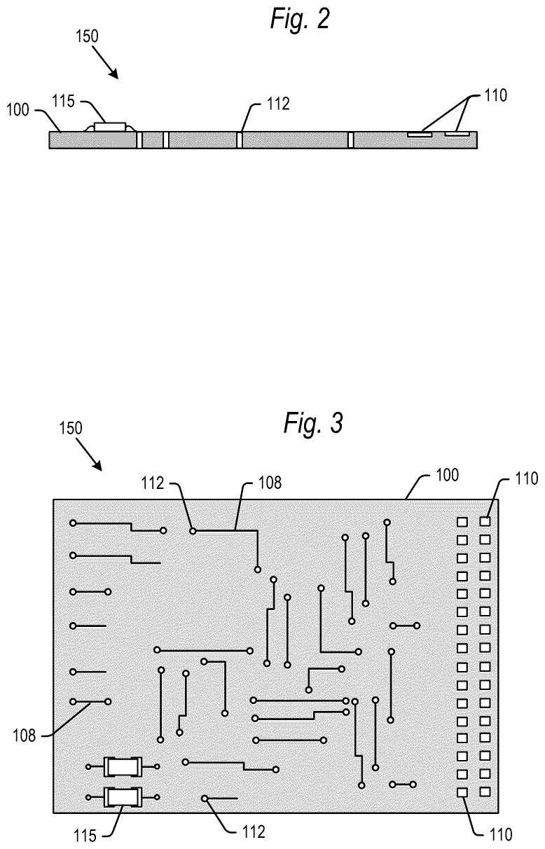

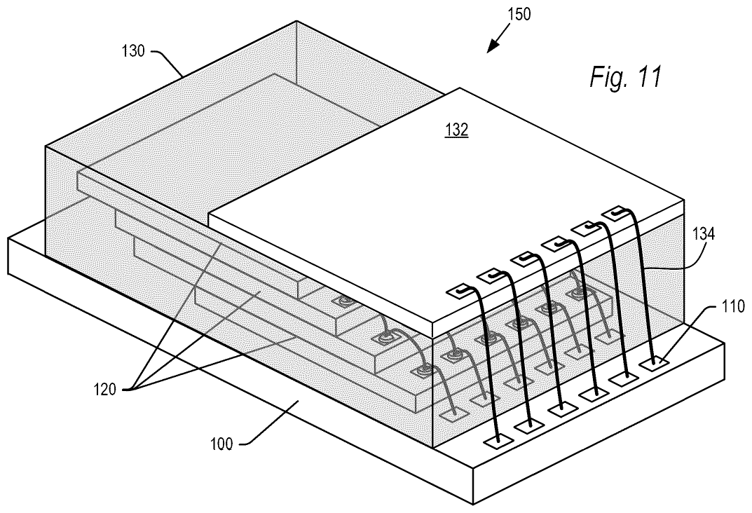

An embodiment of the present technology will now be explained with reference to the flowchart of FIG. 1 and the edge, top and perspective views of FIGS. 2 through 20. The figures show a single semiconductor device 150, or portions thereof, but it is understood that the semiconductor device of the present technology may be assembled from a panel of substrates to achieve economies of scale.

In step 200, a substrate 100 is formed, as shown in the edge and top views of FIGS. 2 and 3. Substrate 100 is a signal-carrier medium provided for transferring electrical signals between semiconductor dies mounted on the substrate and a host device, as explained below. In one embodiment of the present technology, the substrate 100 may be a printed circuit board, but the substrate 100 may be formed of other signal-carrier mediums such as leadframes, flex tapes, interposers or combinations thereof in further embodiments.

The substrate 100 may be comprised of conductive layers 104 sandwiching a dielectric core 106. The substrate may include multiple cores 106, each surrounded by a conductive layer 104, in further embodiments. The conductive layers 104 may be formed of copper or copper alloys, plated copper or plated copper alloys, Alloy 42 (42Fe/58Ni), copper plated steel, or other metals and materials suitable for use on substrate panels. The core 106 may be formed of various dielectric materials such as for example, polyimide laminates, epoxy resins including FR4 and FR5, bismaleimide triazine (BT), and the like. The core 106 may be ceramic or organic in alternative embodiments.

The conductive layers 104 may be etched in photolithographic processes into conductance patterns including electrical traces 108 and contact pads 110. The contact pads 110 are provided to receive bond wires and/or surface mounted components such as semiconductor dies as explained below. Vias 112 may also be formed through the substrate 100 to electrically couple different layers of the substrate. The pattern of traces 108, pads 110 and vias 112 shown in figures is by way of example only and each may vary in further embodiments.

Referring again to FIG. 1, the completed substrate 100 may be inspected and operationally tested in step 202. These inspections may for example include an automatic optical inspection (AOI), an automated visual inspection (AVI) and/or a final visual inspection (FVI) to check for defects, contamination, scratches and discoloration. One or more of these steps may be omitted or performed in a different order in further embodiments.

Assuming the substrate 100 passes inspection, one or more passive components 115 (FIGS. 2 and 3) may next be affixed to a top surface 116 of the substrate 100 in a step 204. The one or more passive components may include for example one or more capacitors, resistors and/or inductors, though other components are contemplated. The passive components 115 shown are by way of example only, and the number, type and position may vary in further embodiments.

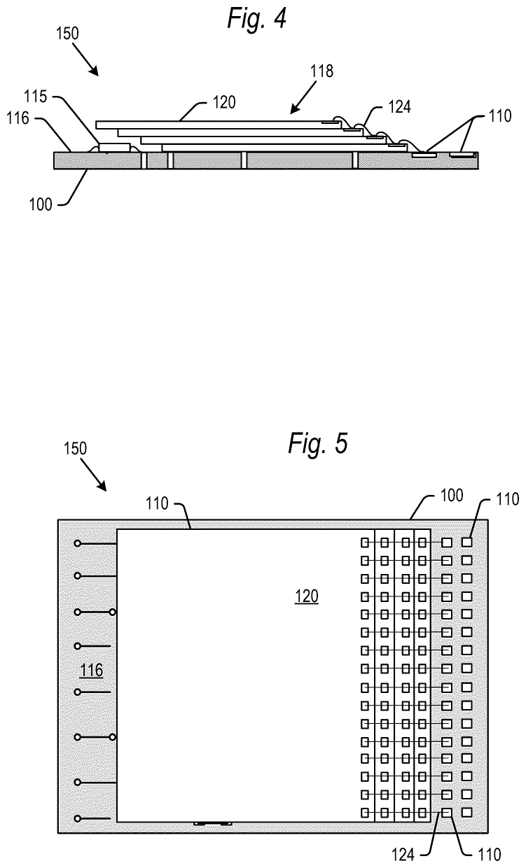

In step 210, a die stack 118 including one or more semiconductor memory dies 120 may be formed on top of the substrate 100 as shown in the edge and top views of FIGS. 4 and 5, respectively. The semiconductor memory dies 120 may for example be flash memory dies such as 2D NAND flash memory or 3D BiCS (Bit Cost Scaling), V-NAND or other 3D flash memory, but other types of dies 120 may be used. These other types of semiconductor dies include but are not limited to RAM such as an SDRAM, DDR SDRAM, LPDDR and GDDR.

Where multiple semiconductor dies 120 are included, the semiconductor dies 120 may be stacked atop each other in an offset stepped configuration to form a die stack as shown in FIGS. 4 and 5. The number of dies 120 shown in the stack is by way of example only, and embodiments may include different numbers of semiconductor dies, including for example 1, 2, 4, 8, 16, 32 or 64 dies. There may be other numbers of dies in further embodiments. The dies 120 may be affixed to the substrate and/or each other using a die attach film (DAF) layer. As one example, the die attach film may be cured to a B-stage to preliminarily affix the dies 120 in the stack, and subsequently cured to a final C-stage to permanently affix the dies 120 to the substrate 100.

In step 214, the semiconductor memory dies 120 may be electrically interconnected to each other and to the contact pads 110 of the substrate 100. FIGS. 4 and 5 show bond wires 124 formed between corresponding die bond pads on respective dies 120 down the stack, and then bonded to contact pads 110 on the top surface 116 of the substrate 100. The bond wires 124 may be formed by a ball-bonding technique, but other wire bonding techniques are possible. The semiconductor dies 120 may be electrically interconnected to each other and the substrate 100 by other methods in further embodiments, including by through-silicon vias (TSVs) and flip-chip technologies.

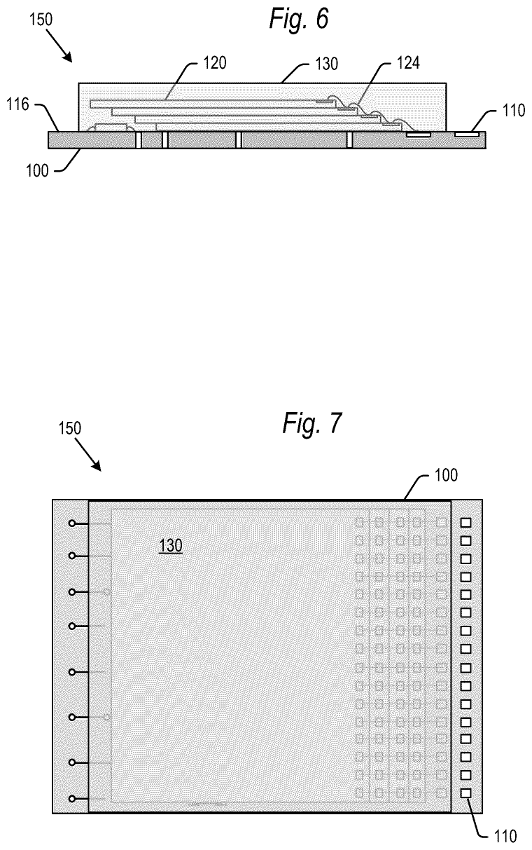

Following electrical connection of the dies 120 to the substrate 100, the dies 120 and bond wires 124 may be buried in a film layer 130 in step 218 as shown in the edge, top and perspective views of FIGS. 6, 7 and 8, respectively. The film layer may completely embed the memory dies 120 and bond wires 124. In embodiments, the film layer 130 may be an epoxy which, in examples has properties including low bleed, non-voiding, low internal stress, low warpage, and electrically non-conductive. Examples of such film layers include 6202C epoxy from Henkel AG & Co. KGaA having a corporate headquarters in Düsseldorf, Germany. Other epoxies may be used in alternative embodiments, including for example YizBond® BS1001 epoxy from YizTech, Co., Ltd. of Taiwan, and AHS-996E epoxy from 3M Company having a corporate headquarters in St. Paul, MN, USA. It is understood that other epoxies, and SMT adhesives other than epoxies, may be used for film layer 130 in further embodiments.

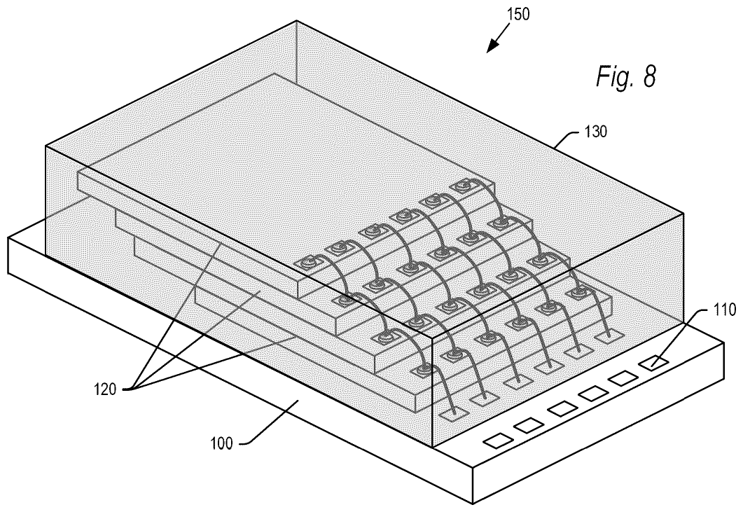

In examples, the film layer 130 may be printed directly onto the surface 116 of substrate 100, as an A-stage liquid or low viscosity paste. A thin film printer may be used, though other printers may be used for applying film layer 130 in further embodiments. In one example, a stencil may be positioned on a panel of substrates 100, and the liquid or paste may be printed onto the substrate on top of the stencil. The stencil has apertures in positions and shape that align over the memory dies 120. Thus, when the A-stage epoxy is applied to the surface 116, the epoxy is screened from all portions of the substrate panel except where the apertures are. The result is that the A-stage film layer 130 is applied over the memory dies 120, in the shape shown for example in FIG. 8. The shape and position of the layer 130 on the substrate 100 may be provided to match the shape and position of the memory dies 120 and bond wires 124 to the substrate 100. However, the stencil may have apertures in other shapes to form the film layer 130 in other shapes in further embodiments. The film layer 130 may be applied without use of a stencil in further embodiments.

After the A-stage epoxy is applied, a squeegee may be used to ensure full and even coverage of the A-stage epoxy within the aperture of the stencil. After the liquid or paste epoxy is applied, the squeegee may be moved over the surface of the stencil, in contact with the stencil, so that the epoxy is worked into (i.e., forced down into) the apertures of the stencil in an evenly applied layer. In embodiments, the squeegee may be integrated as part of the print head assembly so that the A-stage epoxy is spread by the squeegee as it is applied by the print head assembly. The print head assembly and squeegee may be separate in further embodiments. The film layer 130 may be applied by methods other than printing in further embodiments. Such further examples include thin film deposition techniques, and jet dispensing techniques. In embodiments, the film layer may have a thickness of 150 μm to 250 μm, though it may be thinner or thicker than that, depending in part on the number of dies 120 as well as the height of the memory dies 120 and bond wires 124.

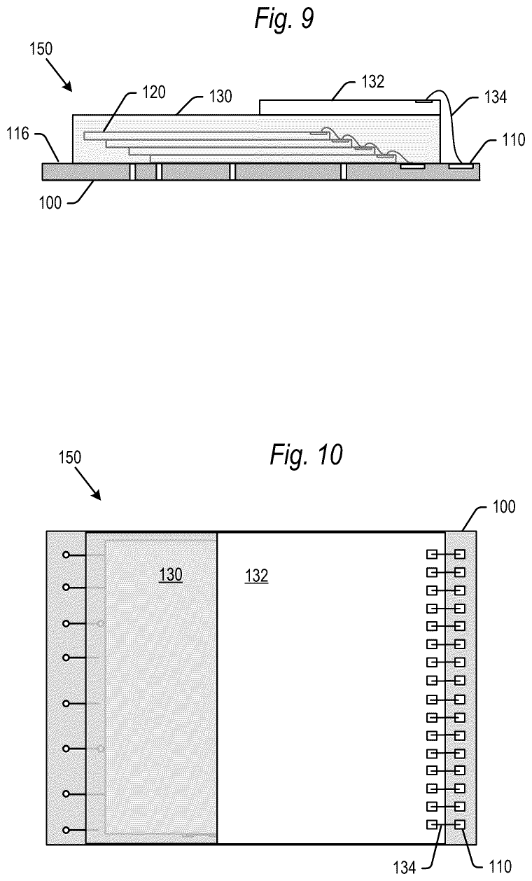

In embodiments, after film layer 130 is formed on substrate 100, a controller die 132 may be mounted on top of the film layer 130 in step 220 and as shown in the edge, top and perspective views of FIGS. 9, 10 and 11, respectively. In embodiments, the controller die 132 may be an ASIC for controlling the read/write operations to and from the semiconductor dies 120. In further embodiments, the controller die 132 may be a specialized processor such as a graphics processing unit (GPU) or an artificial intelligence (AI) processing unit. As explained below, in further embodiments, other components may be mounted on top of the film layer 130 instead of or in addition to a controller die, including for example a multiplexer or a spacer block. The footprint (length and width) of the film layer 130 may be at least as large as the footprint of the controller die 132.

In the example where the film layer 130 is applied as an A-stage epoxy, the epoxy may be cured to a B-stage epoxy before positioning the controller die 132 thereon. Curing may be accomplished by heating the A-stage film layer 130 for 90 minutes at 125° C. Other heating temperatures and times are contemplated. Depending on the material of the film layer 130, the film layer may be cured to a B-stage by ultraviolet irradiation in further embodiments.

The controller die 132 may include a die attach film (DAF) layer on its bottom surface. When the controller die 132 is placed on the B-stage film layer 130, the substrate may be heated to soften the B-stage film layer 130 to promote adhesion between the film layer 130 and the DAF layer. After the control die 132 is mounted, the film layer 130 and controller die DAF layer may be heated so that the film layer 130 is cured its final C-stage, thereby firmly mounting the controller die 132 on the film layer 130. In alternative embodiments, the DAF layer on the controller die 132 may be omitted, with the controller die being affixed to the film layer 130 upon curing of the film layer 130 to its final C-stage. The film layer 130 may be cured to its C-stage by heating with a 30 minute ramp up from room temperature to 100° C. to 175° C., plus another 30 minutes at 100° C. to 175° C. The film layer may be cured to its C-stage using other heating temperatures and times. Depending on the material of the film layer 130, the film layer may be cured to the C-stage ultrasonically in further embodiments.

In further embodiments, the film layer 130 may be cured to its final C-stage before the controller die 132 is mounted on the film layer 130. In such embodiments, adhesion of the controller die 132 to the film layer 130 may be accomplished using the DAF layer on a bottom surface of the controller die.

In step 224, the controller die may be electrically coupled to the substrate 100 by a second set of bond wires 134 formed between die bond pads on the controller die 132 and the contact pads 110 on the substrate 100 as shown in FIGS. 9-11. While all of the bond wires are shown extending from a single edge of the controller die 132, it is understood that die 132 may have die bond pads and bond wires around two or more edges.

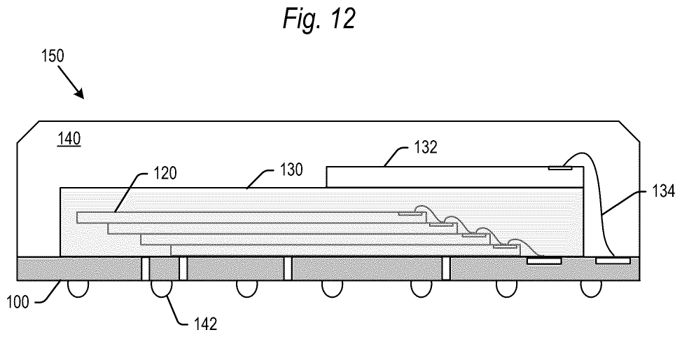

Following mounting and electrical coupling of the controller die 132, the semiconductor device 150 may be encapsulated in a mold compound 140 in a step 226 and as shown in the edge view of FIG. 12. Mold compound 140 may include for example solid epoxy resin, Phenol resin, fused silica, crystalline silica, carbon black and/or metal hydroxide. Such mold compounds are available for example from Sumitomo Corp. and Nitto-Denko Corp., both having headquarters in Japan. Other mold compounds from other manufacturers are contemplated. The mold compound may be applied according to various known processes, including by transfer molding or injection molding techniques. The encapsulation process may be performed by FFT (Flow Free Thin) compression molding in further embodiments.

As shown in FIG. 10, after the encapsulation step 226, solder balls 142 may be applied to the contact pads 110 on a bottom surface of the substrate 100 in step 228. The solder balls 142 allow the device 150 to be mounted to a host device such as a printed circuit board (not shown). The solder balls 142 may be applied at an earlier stage in the assembly of semiconductor device 150.

As noted above, the semiconductor devices 150 are formed on a panel of substrates 100 for economies of scale. The respective devices may be singulated in step 230 from the panel to form the finished semiconductor device 150 shown in FIG. 12. Each semiconductor device 150 may be singulated by any of a variety of cutting methods including sawing, water jet cutting, laser cutting, water guided laser cutting, dry media cutting, and diamond coating wire cutting. While straight line cuts will define generally rectangular or square shaped semiconductor device 150, it is understood that semiconductor device 150 may have shapes other than rectangular and square in further embodiments of the present invention.

The film layer 130 of the present technology provides advantages including protection of the semiconductor memory dies during the assembly process, such as for example during the encapsulation process. In conventional devices including thin semiconductor dies, the forces exerted during the encapsulation process can crack or otherwise damage the thin dies. The film layer also prevents wire sweep, where the bond wires get bent out of shape during the encapsulation process. Further still, the film layer provides a base so that the controller die 132 may be mounted on top of the die stack to reduce the overall footprint of the substrate 100 and finished semiconductor device 150.

As indicated above, other components may be placed on top of the film layer 130 in further embodiments. These other components include a multiplexer (MUX), which in general is an electronic device that selects one of several input signals from a host device and forwards the chosen input into a single line of one of the dies 120. These other components further include a spacer block used to space components above the substrate 100. The spacer block may be formed of various materials, depending on the desired thermal conductivity and mechanical strength. These materials include for example various metals including copper, various ceramics and various polymers.

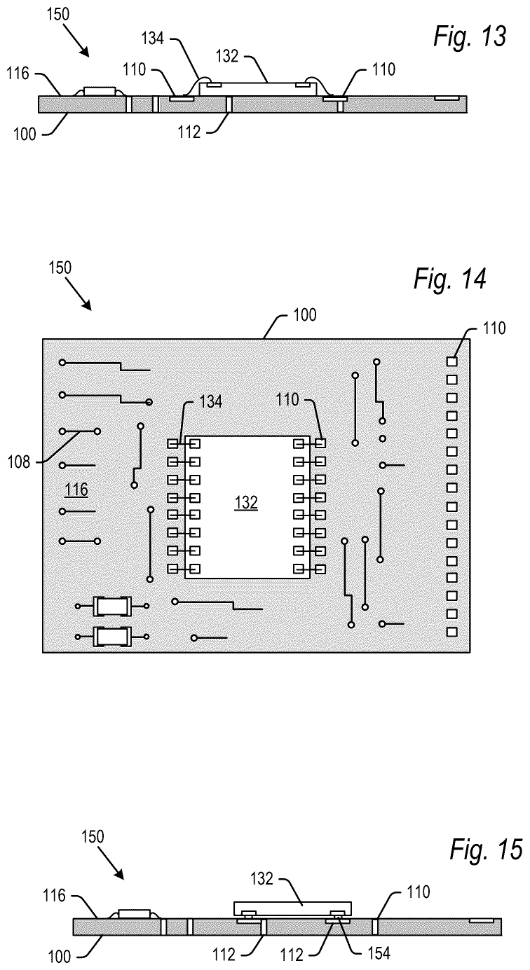

In embodiments described above, the memory dies 120 were buried in the film layer 130, and the controller die or other component was mounted on top of the film layer 130. However, this order may be reversed in further embodiments. Such an embodiment will now be described with reference to the edge and top views of FIGS. 13-20.

Referring initially to the edge and top views of FIGS. 13-15, this embodiment may begin with a substrate 100 as described above, and a controller die 132 as described above bonded directly to an upper surface 116 of the substrate 100. The controller die 132 may be electrically coupled to the substrate 100 using bond wires 134 as shown in FIGS. 13 and 14 and as described above. Alternatively, the controller die 132 may be electrically coupled to the substrate 100 using a flip-chip technique as shown in FIG. 15, where die bond pads on the controller die are directly bonded to contact pads 110 on the substrate, for example using solder bumps 154.

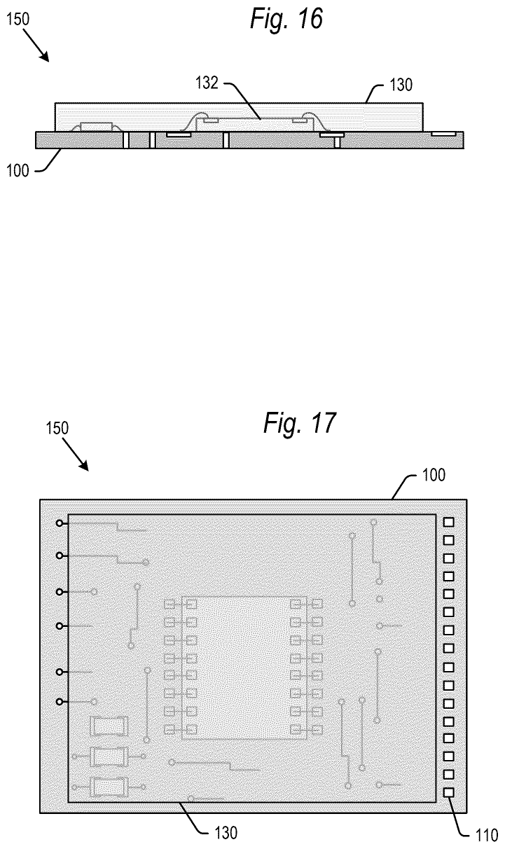

Referring now to the edge and top views of FIGS. 16 and 17, respectively, a film layer 130 may be formed on surface 116 of the substrate 100 with the controller die 132 buried within the film layer. The film layer 130 may be formed of the same materials described above, and by any of the processes as described above.

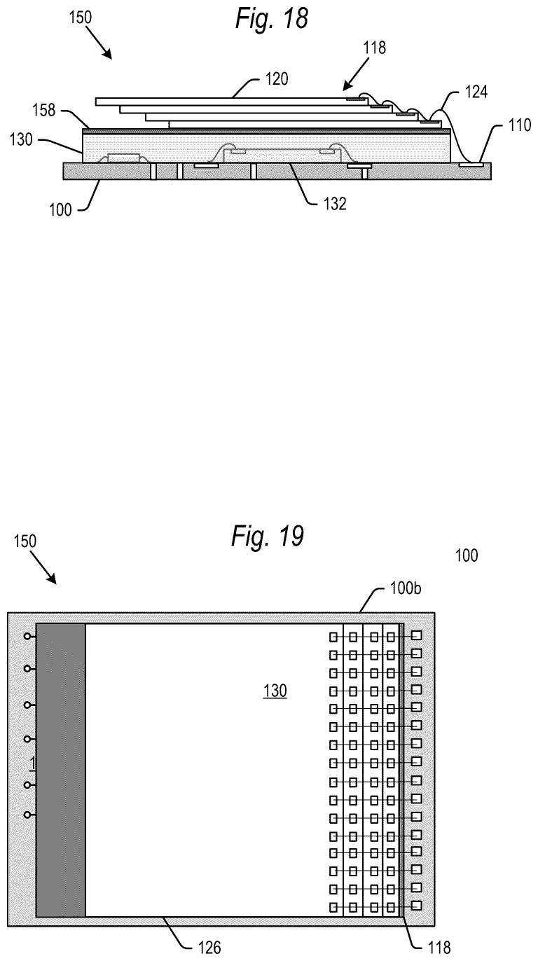

Referring now to the edge and top views of FIGS. 18 and 19, a spacer layer 158 may be formed on top of the film layer 130, and thereafter, a die stack 118 including one or more semiconductor memory dies 120 may be formed on top of the spacer layer 158. The spacer layer 158 may be formed of any of the materials set forth for the above-described spacer layer, and may be included to provide the desired thermal or mechanical properties for a base on which the die stack 118 is mounted. The spacer layer 158 may be mounted on upper surface of the film layer 130 by any of the methods described above by which the controller die 132 was affixed to the upper surface of the film layer 130. The spacer layer 158 may however be omitted in further embodiments.

The semiconductor memory dies 120 may be as described above, and may be electrically coupled to each other and the contact pads 110 of substrate 100 using bond wires 124 as described above. The footprint (length and width) of the film layer 130 and spacer layer 158 may be at least as large as the footprint of the bottommost semiconductor memory die 120 in stack 118. The die stack 118 may be affixed to each other and to the spacer layer 158 by a DAF layer formed on a bottom surface of the memory dies 120.

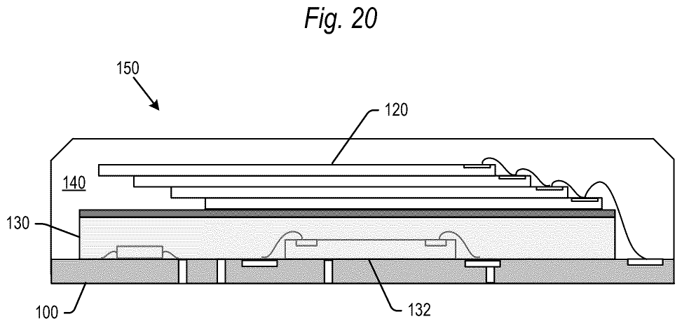

The semiconductor device 150 may next be encapsulated in a mold compound 140 as shown in the edge view of FIG. 20. The mold compound 140 may be formed of any of the materials, and in any of the processes, set forth above with respect to previously-described embodiments. After encapsulation, the individual semiconductor devices may be singulated to provide the finished semiconductor device shown in FIG. 20.

As in the above-described embodiment, the film layer 130 in semiconductor device 150 shown in FIGS. 13-20 provides advantages with regard to protection of the controller die 132 and bond wires 134 connected thereto. The film layer 130 also allows the memory die stack 118 to be formed directly above the controller die 132, thereby reducing the overall size of the substrate 100 and the semiconductor device 150.

In summary, in one example, the present technology relates to a semiconductor device, comprising: a substrate; a stack of one or more memory dies surface mounted to the substrate; bond wires electrically coupling the stack of one or more memory dies to each other and the substrate; a film layer having a first surface positioned against the substrate, and a second surface opposite the first surface, the stack of one or more semiconductor dies and the bond wires being embedded within the film layer; and a component mounted to the second surface of the film layer.

In a further example, the present technology relates to a semiconductor device, comprising: a substrate; a controller die directly mounted to the substrate; a film layer having a first surface positioned against the substrate, and a second surface opposite the first surface, the controller die being embedded within the film layer; a stack of one or more memory dies mounted to the second surface of the film layer; and bond wires electrically coupling the stack of one or more memory dies to each other and the substrate.

In another example, the present technology relates to a semiconductor device, comprising: a substrate; a stack of one or more memory dies surface mounted to the substrate; a first set of bond wires electrically coupling the stack of one or more memory dies to each other and the substrate; means, applied to the substrate, for embedding the stack of one or more semiconductor dies and the first set of bond wires; a controller die mounted on the embedding means; and a second set of bond wires electrically coupling the controller die to the substrate.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A semiconductor device, comprising:
a substrate;
a stack of one or more memory dies surface mounted to the substrate;
bond wires electrically coupling the stack of one or more memory dies to each other and the substrate;
a film layer having a first surface positioned against the substrate, and a second surface opposite the first surface, the stack of one or more semiconductor dies and the bond wires being embedded within the film layer; and
a component mounted to the second surface of the film layer.

2. The semiconductor device of claim 1, wherein the component is a controller die.

3. The semiconductor device of claim 2, wherein the bond wires comprise a first set of bond wires, the semiconductor device further comprising a second set of bond wires electrically coupling the controller die to the substrate.

4. The semiconductor device of claim 1, wherein the component is a multiplexer.

5. The semiconductor device of claim 1, wherein the component is a spacer layer.

6. The semiconductor device of claim 1, further comprising an encapsulant for encapsulating the film layer and component.

7. The semiconductor device of claim 1, wherein the film layer is a curable epoxy.

8. The semiconductor device of claim 7, wherein the film layer on the substrate is cured from an A-stage to a C-stage.

9. The semiconductor device of claim 7, wherein the film layer on the substrate is cured from a B-stage to a C-stage.

10. The semiconductor device of claim 1, wherein the film layer is formed on the substrate in a shape and position at least as large as the component.

11. The semiconductor device of claim 1, wherein the semiconductor device is a flash memory package.

12. A semiconductor device, comprising:
a substrate;
a controller die directly mounted to the substrate;
a film layer having a first surface positioned against the substrate, and a second surface opposite the first surface, the controller die being embedded within the film layer;
a stack of one or more memory dies mounted to the second surface of the film layer; and
bond wires electrically coupling the stack of one or more memory dies to each other and the substrate.

13. The semiconductor device of claim 12, wherein the bond wires comprise a first set of bond wires, the semiconductor device further comprising a second set of bond wires electrically coupling the controller die to the substrate.

14. The semiconductor device of claim 12, wherein the controller die is flip-chip mounted to the substrate.

15. The semiconductor device of claim 12, further comprising an encapsulant for encapsulating the film layer and stack of one or more memory dies.

16. The semiconductor device of claim 12, wherein the film layer is a curable epoxy.

17. The semiconductor device of claim 16, wherein the film layer on the substrate is cured from an A-stage to a C-stage.

18. The semiconductor device of claim 16, wherein the film layer on the substrate is cured from a B-stage to a C-stage.

19. The semiconductor device of claim 12, further comprising a die attach film attaching a bottommost memory die of the stack of one or more memory dies to the second surface of the film layer.

20. A semiconductor device, comprising:
a substrate;
a stack of one or more memory dies surface mounted to the substrate;
a first set of bond wires electrically coupling the stack of one or more memory dies to each other and the substrate;
means, applied to the substrate, for embedding the stack of one or more semiconductor dies and the first set of bond wires;
a controller die mounted on the embedding means; and
a second set of bond wires electrically coupling the controller die to the substrate.
